(19) United States
(12) Patent Application Publication
(10) Pub. No.: US 2005/0270065 A1
(43) Pub. Date: Dec. 8, 2005

(54) Coms buffer having higher and lower voltage operation

(76) Inventors: Dipankar Bhattacharya, Maeungie, PA (US); Brijendra Dobriyal, Allentown, PA (US); Bernard L. Morris, Emmaus, PA (US)

Correspondence Address: MANELLI DENISON & SELTER PLLC,;7th Floor, 2000 M Street, N.W., Washington, DC, 20036-3307, US

(21) Appl. No.: 10/859,211

(22) Filed: Jun. 3, 2004

(51) Int. Cl. H03K 19/0175

(52) U.S. Cl. 326/81

(57) ABSTRACT

A buffer design for an integrated circuit that not only recognizes, but improves upon the skew problem as described above that is particularly problematic in cases where the output buffer supply voltage is particularly close or the same as the voltage of the signals coming from the core of an IC. Translator-up circuits associated with output buffers are implemented in parallel with respective selective bypass circuits, allowing the translator-up circuit to be inserted into or removed from a signal path based on the voltage level of a signal received from the inner core and the voltage level required by the output buffer. When the voltage level of the “higher” voltage side is equal to the “lower” voltage signal level, the translator-up circuits are bypassed through selection by a selective bypass circuit. Thus, a selective bypass circuit is implemented together with a translator-up circuit to eliminate large signal skew, and to generally speed up circuit performance.

### BACKGROUND OF THE INVENTION

1. Field of the Invention

This invention relates to integrated circuits. More particularly, it relates to the design of input and output buffers in an integrated circuit capable of efficient operation at multiple voltage levels.

2. Background of Related Art

Integrated circuits are an important part of life as we know it today. They are the basis for most all electronic devices, from telephones and answering machines to the most sophisticated computers. An important part of an integrated circuit (IC) is its ability to accept information in, and/or to pass information out. Thus, an IC must interface with the outside world.

While direct electrical connection with internal components of an IC is possible, it would leave the IC vulnerable to external voltages and currents, which may exceed the ability of the internal circuit. To provide both protection of internal components from external signals, as well as to provide amplified output signals, most signals input or output on a typical IC interfacing with the external world are ‘buffered’.

A buffer is usually a more robust circuit capable of handling typical external signal levels, as well as capable of driving a predetermined number of connections to other devices. Though a necessary evil, buffers can utilize excess power in a given application, shortening battery life, requiring larger power sources, etc. Excess use of power can be particularly troublesome where a buffer is operable with multiple voltage levels, e.g., 3.3v, 2.5v, etc.

Complementary Metal-Oxide Semiconductor (CMOS) output buffers in modern ICs translate lower voltage signals from the integrated circuit core to relatively higher voltage signals that are used to drive off-integrated circuit signals. It can be desirable to use a single output buffer to drive a variety of these “higher voltages” (e.g., 3.3v, 2.5v, etc.), including the case where the “lower voltage” value is actually equal to or within a predetermined range of the “higher voltage” value. Known voltage translator circuits that allow the normally “lower” voltage signals to be translated up in voltage to the “higher” voltage values does not work very well if the “higher” voltage is equal to the “lower” voltage value. Our invention eliminates this problem.

In conventional systems, voltage translator circuitry is typically left in place. Moreover, conventional voltage translator circuits produce very long delays, and more importantly a very large skew, in the signal path when the “higher” voltage level is lowered down to the “lower” voltage level.

FIG. 4 shows a conventional output buffer 506 capable of providing a low output, a high output and a high impedance output. As shown in FIG. 4, the conventional output buffer receives an enable signal EN, and a logic input signal A. If the enable signal EN is LOW, then output of a NAND gate X1 will always be HIGH, regardless of the value of the input signal A. This forces node P HIGH, and turns OFF the p-channel transistor M1. Likewise, when the enable signal EN is LOW, the output of the NOR gate X2 will always be LOW, as one of its inputs is the inverse ENB of the enable signal, which is logically inverted by inverter X3. This forces node N LOW, turning OFF the n-channel transistor M0. In this case, the output Z of the buffer is said to be in a higher impedance state, or tri-state.

When the enable signal EN is HIGH, the effect of NAND gate X1 and NOR gate X2 is to force both nodes P and N to be the opposite of the input signal A. Thus, when the input signal A is HIGH, nodes N and P are LOW. This turns transistor M1 ON, and turns transistor M0 OFF, forcing the output Z HIGH. When the input signal A is LOW, then both nodes N and P are HIGH. This turns transistor M0 ON, and turns transistor M1 OFF, forcing node Z LOW.

The circuit of FIG. 4 implicitly assumes that the voltage levels of the input signal A and the enable signal EN are the same as those of the output signal Z. This may not always be the case, given the availability of lower voltage circuits, e.g., requiring only 3.3v to operate, or 2.5v, etc.

In the disclosed embodiment of FIG. 4, a nominal power supply voltage of 3.3 volts is presumed for the drive transistors M0, M1 of the output buffer, as implied by the notation VDD33. In many modern ICs, the voltage used inside the core of the integrated circuit may be much lower than the voltages used in many output buffers. For instance, typical values for the core voltage may be between 1.0 volt and 1.5 volts, while voltages for the output stage are typically between 2.5 volts and 3.3 volts.

To move from the lower voltage circuit core to the higher voltage buffer voltage levels, a voltage translation is performed. Typically, to translate between the lower core voltage and the higher buffer voltage, a special circuit called a translator-up, or TRANU, is used. Without a translator-up circuit, if a lower voltage signal (e.g., VDD12=1.2V), was simply applied to an inverter operating at a higher voltage (e.g., VDD33=3.3V), there would be a good deal of DC power drawn from the inverter when the 1.2V signal was HIGH. This is because the p-channel transistor of the inverter would not be fully turned OFF. In fact, the gate-to-source voltage VGS would be equal to 3.3V−1.2V=2.1V, which would produce a waste of a large amount of power.

FIGS. 5 to 7 show a conventional output buffer including a translator-up or TRANU circuit.

FIG. 5 is a block diagram depicting a conventional output buffer including translator-up circuits. As shown in FIG. 5, an enable signal EN and an input signal A are each input to separate translator-up circuits X4, X5. The translator-up circuits X4, X5 translate voltage signals from the lower voltage core of an IC to the signal level corresponding to the power rail of the output drivers and logic control circuit 506.

FIG. 6 shows additional detail of the output drivers and logic control 506 of the conventional output buffer shown in FIG. 5. As shown in FIG. 6, the translator-up circuits X4, X5 each allow a lower voltage input signal IN to drive a higher voltage output signal OUT without causing the output buffer 600 to draw current (i.e., DC power) from the power sources. The output drivers and logic control 506 include the same drive transistors M2 and M3, the same NAND gate X1, the same NOR gate X2, and the same inverter X3 as did the high impedance state buffer shown in FIG. 4.

FIG. 7 shows a detailed schematic diagram of the translator-up (TRANU) circuits X4, X5 of FIGS. 5 and 6 in more detail. As shown in FIG. 7, the translator-up circuits X4, X5 comprise an inverter stage X3 formed by transistors M4 and M6 with a current path between ground VSS and the lower voltage power rail VDD12. A first current path between the higher voltage rail VDD33 and ground VSS is formed by a series connection of a p-channel CMOS transistor MP1, and an n-channel CMOS transistor MN1. A second current path between the higher voltage rail VDD33 and ground VSS is formed by a series connection of another p-channel CMOS transistor MP2 and another n-channel CMOS transistor MN2. The output from the inverter stage X3 drives the gate of transistor MN1, and the input to the inverter stage X3 drives the gate of transistor MN2. The gates of the p-channel transistors MP1 and MP2 are cross coupled to the nodes between the respective transistors MP1, MP2 and its series connection to respective transistors MN1, MN2. The node formed between transistors MP2 and MN2 drives the gates of a p-channel transistor M7 in series with an n-channel transistor M5 forming an output buffer for the translator-up circuits X4, X5.

The conventional translator-up circuits X4, X5 of FIGS. 5-7 eliminate the earlier conventional problem of power draw caused by a differential between supply voltages by applying only 1.2V signals to n-channel transistors MN1 and MN2. This is because the gate of transistor MN2 is connected directly to the input signal IN of the translator-up circuit X4, X5, while the gate of the transistor MN1 is connected to inversion INB of the input signal. The inverted input signal INB is produced by the inverter formed by transistors M6 and M4.

When the input signal IN is HIGH, transistor MN2 is ON while MN1 is OFF. This pulls node I1 down, turning p-channel transistor MP1 ON, which pulls node I2 up to VDD33. The output signal OUT is thus HIGH. On the other hand, when the input signal IN is low, transistor MN1 is ON, and transistor MN2 is OFF. This in turn pulls node I2 down, turning transistor MP2 ON, which pulls node I1 HIGH, forcing the output signal OUT to be LOW.

Thus, at any given time, the translator-up circuits X4, X5 have all transistors fully turned ON or turned OFF, so there is no DC power used at any given period of time.

However, the conventional output buffer circuit shown in FIGS. 5-7 is sensitive in that the n-channels of transistors MN1 and MN2 must be strong enough to reverse the logic state on nodes 11 and 12 from the logic state that the cross-coupled p-channels of transistors MP1 and MP2 are holding them in whenever the input signal IN changes its logic state.

Moreover, and importantly, there is an inherent skew to the output of the translator-up circuit X4, X5. In operation, when the input signal IN goes HIGH, it pulls node I1 down directly. But when the input signal IN goes LOW, it acts through the inverter driving node INB to pull node I2 LOW. This in turn pulls node I1 HIGH through transistor MP2. As a result, the HIGH-to-LOW transition is generally slower than the LOW-to-HIGH transition. This produces a skew on the circuits output signal, caused by this delay between transition directions.

This skew in the output signal of the output buffer is greater as the voltage differential between the lower voltage level of the core of the IC, and the higher voltage level of the output buffer (e.g., as the voltage level of the power source VDD33 to the translator-up circuit is lowered to 2.5v technology, etc.), the skew can affect greatly the strength of the p-channel transistors MP1 and MP2 much more than it does the n-channel transistors MN1 and MN2. In the limiting case where the power supply voltage VDD33 is reduced from a voltage level of, e.g., 3.3v to a much lower level of, e.g., 1.2v, the conventional translator-up circuit barely works properly, if at all.

### SUMMARY OF THE INVENTION

In accordance with the principles of the present invention, an integrated circuit comprises an inner core adapted to operate with a first, lower voltage. An output driver operates with a second, higher voltage. A translator-up circuit translates a voltage level of a signal from the inner core to a higher voltage level for use by the output driver. A selectable bypass circuit allows the signal from the inner core to bypass the translator-up circuit when a translated voltage level is not required.

In accordance with another aspect of the present invention, a method of interfacing a lower voltage portion of an integrated circuit with a higher voltage portion of said integrated circuit comprises allowing a lower voltage signal from the lower voltage portion of the integrated circuit to pass through a translator-up circuit before driving an output driver in the higher voltage portion. The lower voltage signal is allowed to bypass the translator-up circuit when a voltage level of a power rail of the lower voltage portion is within a given percentage of a voltage level of a power rail of the higher voltage portion.

### BRIEF DESCRIPTION OF THE DRAWINGS

Features and advantages of the present invention will become apparent to those skilled in the art from the following description with reference to the drawings, in which:

FIGS. 1-3 show a multiplexing architecture for implementing input and output buffers designed for efficient use of both higher and lower voltages, in accordance with the principles of the present invention.

FIG. 1, in particular, shows the use of a multiplexer together with a translator-up circuit, allowing complete bypass in the case where a ‘higher’ voltage is actually equal to a ‘lower’ voltage.

FIG. 1A shows the use of a multiplexer together with a translator-down circuit, allowing complete bypass in the case where a ‘higher’ voltage is actually equal to a ‘lower’ voltage.

FIG. 2 shows an output buffer as shown in FIG. 1 including selectable bypass of translator-up circuits in more detail.

FIG. 3 shows selectable bypass circuitry including multiplexing architecture for implementing an output buffer designed for efficient use of both higher and lower voltages, in accordance with the principles of the present invention.

FIG. 4 shows a conventional output buffer.

FIGS. 5 to 7 show a conventional output buffer including a translator-up or TRANU circuit.

FIG. 5, in particular, is a block diagram depicting a conventional output buffer including translator-up circuits.

FIG. 6 shows additional detail of the output drivers and logic control of the conventional output buffer shown in FIG. 5.

FIG. 7 shows a detailed schematic diagram of the translator-up (TRANU) circuits of FIGS. 5 and 6 in more detail.

### DETAILED DESCRIPTION OF ILLUSTRATIVE EMBODIMENTS

The present invention provides a buffer design for an integrated circuit that not only recognizes, but improves upon the skew problem as described above that is particularly problematic in cases where the output buffer supply voltage is particularly close or the same as the voltage of the signals coming from the core of an IC.

In accordance with the principles of the present invention, translator-up circuits associated with output buffers are implemented in parallel with respective selectable bypass circuits, allowing the translator-up circuit to be inserted into or removed from a signal path based on the voltage level of a signal received from the inner core and the voltage level required by the output buffer. When the voltage level of the “higher” voltage side is equal to the voltage level of the “lower” voltage side, the translator-up circuits are bypassed through selection by a selectable bypass circuit, such as a multiplexer. Thus, a selectable bypass circuit is implemented together with a translator-up circuit to eliminate large signal skew, and to generally speed up circuit performance.

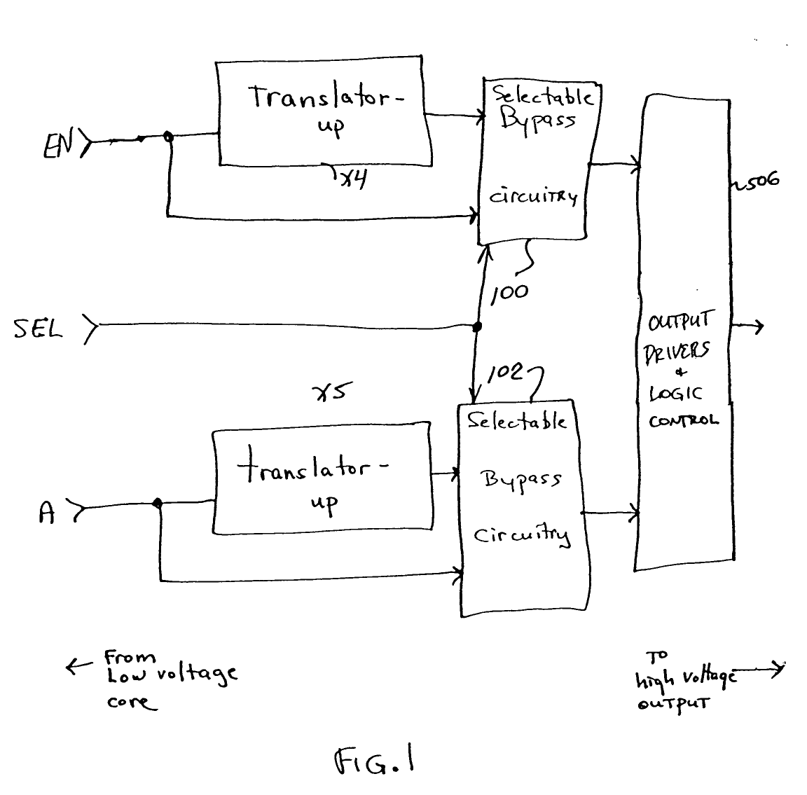

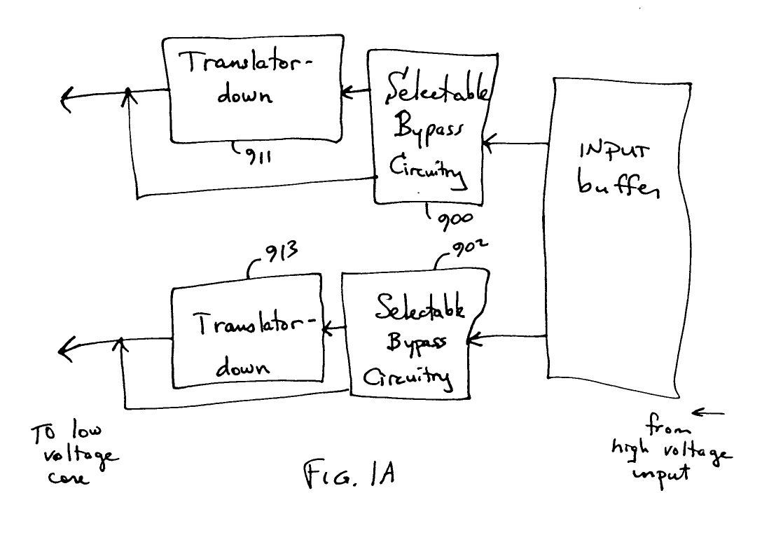

FIGS. 1-3 show a multiplexing architecture for implementing input and output buffers designed for efficient use of both higher and lower voltages, in accordance with the principles of the present invention.

FIG. 1 in particular shows the use of a multiplexer together with a translator-up circuit, allowing complete bypass in the case where a ‘higher’ voltage is actually equal to a ‘lower’ voltage. As shown in FIG. 1, an output buffer includes translator-up circuits X4, X5 between a lower voltage inner core and higher voltage output drivers and logic control 506. Importantly, the translator-up circuits X4, X5 are implemented together with selectable bypass circuitry 100, 102 (multiplexers in the disclosed embodiment), that allow an input signal A and an enable signal EN to each selectively be provided to respective translator-up circuits X4, X5 or to bypass their respective translator-up circuits X4, X5 and be provided directly to the output drivers and logic control 506.

The bypass circuitry 100, 102 is activated to allow bypass of translator-up circuits X4, X5 under the control of an input select signal SEL, which may be multiple independent signals such as a multi-bit signal. In the disclosed embodiments, when the voltage level of a signal from an inner core is a higher voltage (e.g., VDD33) that is very close to, or preferably equal to, a lower voltage of the inner core (e.g., VDD12), the select signal SEL can be activated (e.g., driven HIGH) by relevant comparison circuitry to cause the bypass circuitry to allow the higher voltage level signal to bypass the respective translator-up circuits X4, X5. It is noted that with a multi-bit SEL signal, the transistor-up circuits X4, X5 may be utilized or bypassed independently.

FIG. 1A shows the use of a multiplexer together with a translator-down circuit, allowing complete bypass in the case where a ‘higher’ voltage is actually equal to a ‘lower’ voltage.

In particular, FIG. 1A shows the breadth and flexibility of the present invention, in that selectable bypass circuitry may be implemented to bypass either a translator-up circuit (as shown in FIG. 1) or a translator-down circuit (as shown in FIG. 1A). Any given integrated circuit may include any combination of translator-up circuits with associated selectable bypass circuitry and/or translator-down circuits with associated selectable bypass circuitry.

In FIG. 1A, voltage translation down functions 911, 913 may be implemented for selectable use on signals inbound to the inner core. Respective selectable bypass circuits 900, 902 are implemented to allow bypass of any particular input signal, thus avoiding any skew associated with the translation down function. Skew in the incoming direction to the inner core is not as bad as skew associated with signals being output from the inner core. Nevertheless, every little improvement in a circuit design helps, particularly in high performance applications, so selectable bypass circuits to bypass a translation down of an incoming signal to an inner core has advantages, in accordance with the principles of the present invention.

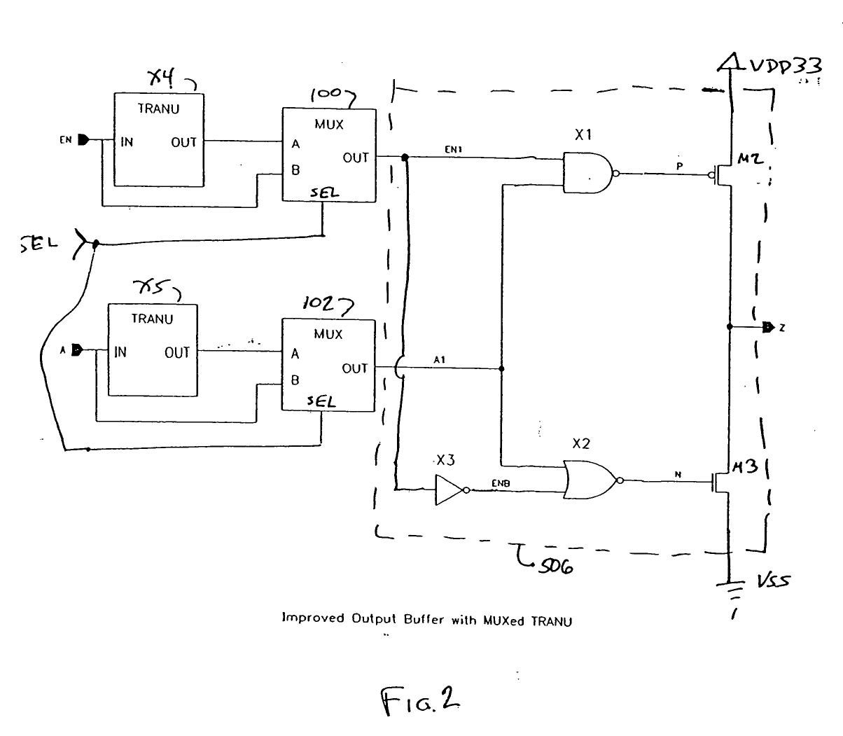

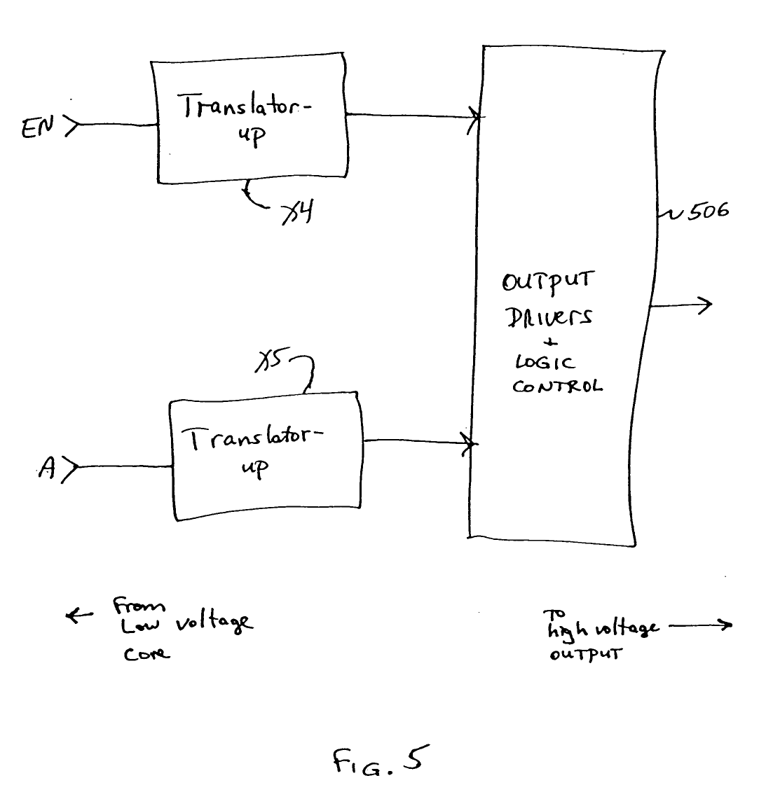

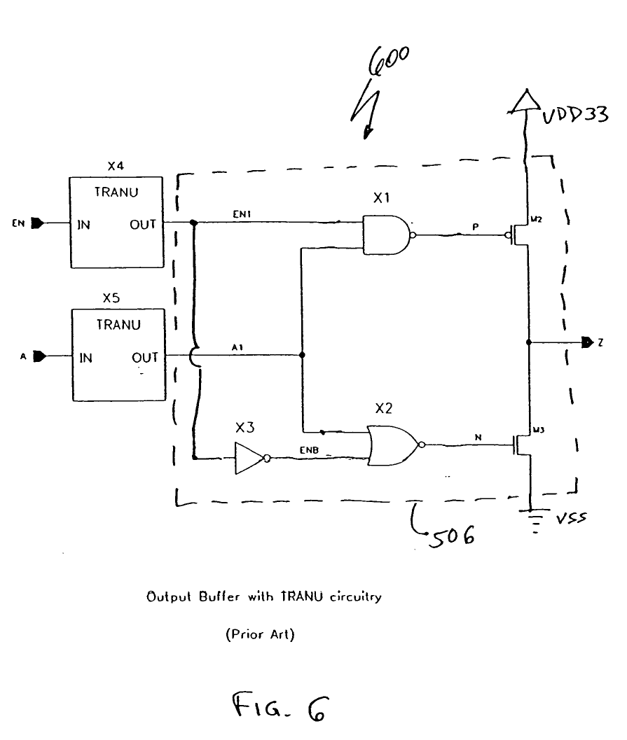

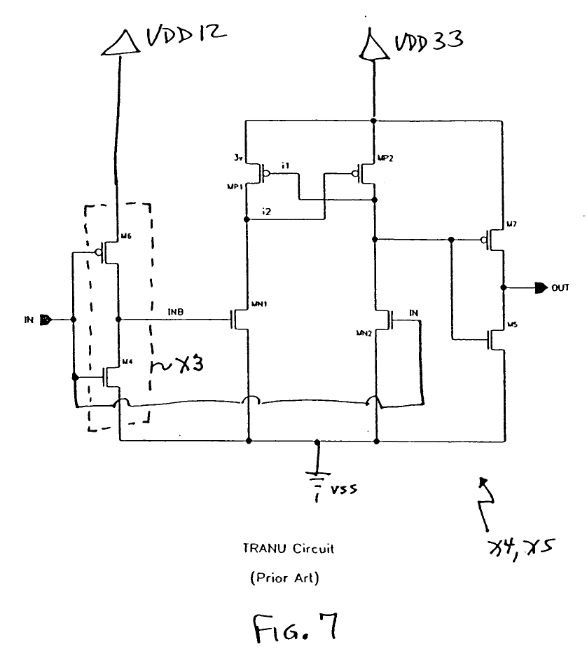

FIG. 2 shows an output buffer as shown in FIG. 1 including selectable bypass of translator-up circuits in more detail. As shown in FIG. 2, output drivers and logic control 506, as well as the translator-up circuits X4, X5, may be just as otherwise used in the conventional output buffer using translator-up circuits X4, X5 shown in FIGS. 5-7. The present invention adds selectable bypass circuitry capable of allowing input of one higher voltage signal and one lower voltage signal, and also capable of allowing selectable bypass of translator-up circuits X4, X5.

Input signal A is input to the translator-up circuit X4, and also to one input of a selectable bypass circuit 100, such as but not limited to a multiplexer. The other input to the selectable bypass circuit 100 receives the output signal OUT from the translator-up circuit X4. The output OUT of the selectable bypass circuit 100 is provided as an input to the output drivers and logic control 506 as the EN1 signal.

Similarly, the enable input signal EN is input to another translator-up circuit X5, and also to one input of another selectable bypass circuit 102, such as but not limited to a multiplexer. The other input to the selectable bypass circuit 102 receives the output signal OUT from the other translator-up circuit X5. The output OUT of this selectable bypass circuit 102 is provided as an input to the output drivers and logic control 506 as the A1 signal.

While shown separately, the selectable bypass circuits 100, 102 may be implemented in a single device, such as a multiplexer having 4 inputs and 2 selectable outputs, within the scope of the present invention.

Since the selectable bypass circuit 100, 102 is implemented to intercept a signal output from the translator-up circuit X4, X5, the intercepted signal will be at a higher voltage level (e.g., at VDD33 level). The other input signal input to the selectable bypass circuit 100, 102 will originate from the core of the IC, and thus will be associated with the lower voltage level. Accordingly, in the preferred embodiment, the selectable bypass circuitry has capability to handle inputs at two different voltage levels.

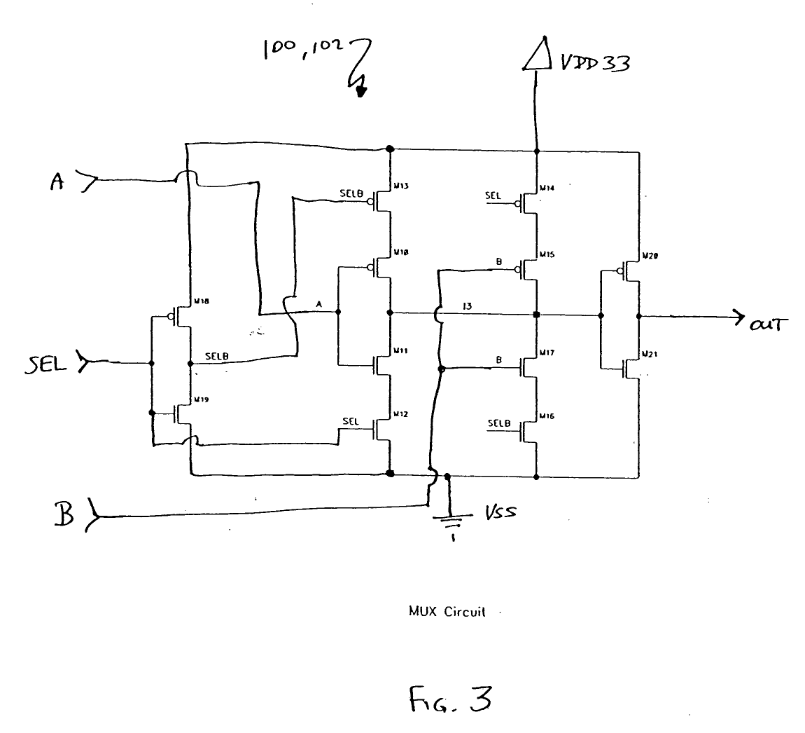

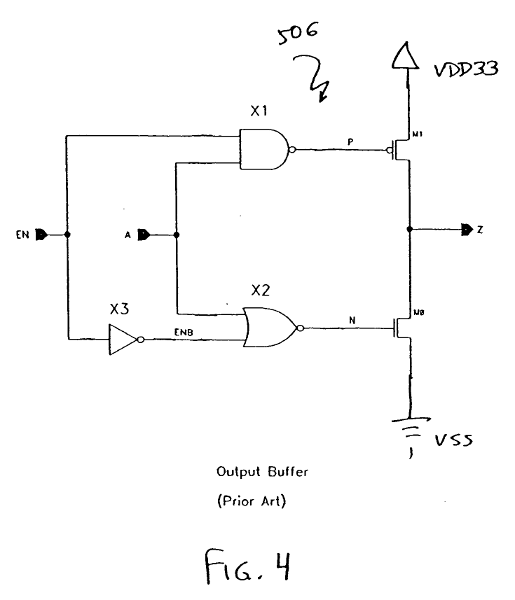

FIG. 3 shows selectable bypass circuitry including multiplexing architecture for implementing an output buffer designed for efficient use of both higher and lower voltages, in accordance with the principles of the present invention. As shown in FIG. 3, a multiplexer architecture is implemented wherein a select input SEL is used to determine which of two inputs A or B is selected to drive the output OUT.

If the select input SEL is HIGH, then the inversion SELB of the select input will be LOW. This turns transistors M12 and M13 ON, and turns transistors M14 and M16 OFF. Under these input conditions, the input signal A is selected to drive the output OUT, while the input B is ignored.

If the select input SEL is LOW, then the inverted select input SELB is HIGH. This turns transistors M14 and M16 ON, and turns transistors M12 and M13 OFF. Under these input conditions, signal B is selected to drive the output OUT, while the input signal A is ignored.

The selectable bypass circuitry 100, 102 includes an ability to receive inputs from both a higher voltage (e.g., VDD33) source, and from a lower voltage (e.g., VDD12) source, as one input will be from the lower voltage core of the IC, while the other will be the higher voltage output of the translator-up circuit.

In operation, when the higher voltage level (e.g., VDD33) is greater than the lower voltage (e.g., VDD12), the select signal SEL will be HIGH. Under these conditions, the input signal A will be selected to drive the output OUT of translator-up circuit X4, as will the enable signal EN will be selected to drive the output OUT its respective translator-up circuit X5.

On the other hand, when the higher voltage equals the lower voltage (VDD33=VDD12), the select signal SEL, supplied by another circuit, is driven LOW. In this case, the selectable bypass circuits 100, 102, bypass the respective input signals (input signal A, enable signal EN) around the respective translator-up circuits X4 and X5.

While the disclosed embodiments envision implementation of a bypass select signal SEL that operates to bypass the translator-up circuits X4, X5 when the higher voltage and lower voltage are equal, it is within the scope of the invention to also allow bypass of the translator-up circuits X4, X5 using the selectable bypass circuitry 100, 102 when the higher voltage is significantly close to the level of the lower voltage. For example, if the voltage level of the higher voltage is within approximately 10%-20% of the voltage level of the lower voltage, it may be preferred to initiate bypass of the translator-up circuits X4, X5 through the selectable bypass circuitry 100, 102.

The selectable bypass circuit of FIG. 3 is shown as a multiplexer by way of example only. Other designs forming a selectable bypass circuit are certainly possible, and within the scope of the present invention.

In the disclosed embodiments, the CMOS transistors in the translator-up circuits and multiplexer are designed based on 3.3 volt technology, but the invention is not limited thereto.

The present invention allows an output buffer, typically placed along the periphery of an integrated circuit, to operate with its higher voltage drive signal level equal to that of the lower voltage core signal when required.

While the invention has been described with reference to the exemplary embodiments thereof, those skilled in the art will be able to make various modifications to the described embodiments of the invention without departing from the true spirit and scope of the invention.

1. An integrated circuit, comprising:
an inner core adapted to operate at a first, lower voltage;
an interface driver adapted to operate at a second, higher voltage;
a translator circuit to translate a voltage level of a signal from one of said first voltage to said second voltage, and said second voltage to said first voltage; and
a selectable bypass circuit adapted to allow said signal to selectively bypass said translator circuit.

2. The integrated circuit according to claim 1, wherein:
said translator circuit is a translator-up circuit.

3. The integrated circuit according to claim 1, wherein:
said translator circuit is a translator-down circuit.

4. The integrated circuit according to claim 2, wherein:
said selectable bypass circuit is operated to bypass said translator-up circuit when said higher voltage is approximately equal to said lower voltage.

5. The integrated circuit according to claim 2, wherein:
said selectable bypass circuit is operated to bypass said translator-up circuit when said higher voltage is within approximately 10% of said lower voltage.

6. The integrated circuit according to claim 2, wherein:
said selectable bypass circuit is operated to bypass said translator-up circuit when said higher voltage is within approximately 20% of said lower voltage.

7. The integrated circuit according to claim 1, wherein:
said lower voltage is approximately 1.2 volts.

8. The integrated circuit according to claim 7, wherein:
said higher voltage is approximately 3.3 volts.

9. The integrated circuit according to claim 1, wherein:
said higher voltage is approximately 3.3 volts.

10. The integrated circuit according to claim 1, wherein:
said higher voltage is approximately 2.5 volts.

11. The integrated circuit according to claim 2, wherein said selectable bypass circuit comprises:
a first input capable of receiving a first input signal at said lower voltage level;
a second input capable of receiving a second input signal at said higher voltage level; and
a select signal input capable of causing said first input signal at said lower voltage level to be replicated on an output when in a first state, and of causing said second input signal at said higher voltage level to be replicated on said output when in a second state.

12. The integrated circuit according to claim 11, wherein:
said lower voltage is approximately 1.2 volts.

13. The integrated circuit according to claim 11, wherein:
said higher voltage is approximately 3.3 volts.

14. A method of interfacing a lower voltage portion of an integrated circuit with a higher voltage portion of said integrated circuit, comprising:
allowing a lower voltage signal from said lower voltage portion of said integrated circuit to pass through a translator-up circuit before driving an output driver in said higher voltage portion; and
allowing said lower voltage signal to bypass said translator-up circuit when a voltage level of a power rail of said lower voltage portion is within a predetermined percentage of a voltage level of a power rail of said higher voltage portion.

15. The method of interfacing a lower voltage portion of an integrated circuit with a higher voltage portion of said integrated circuit according to claim 14, wherein:
said bypass is selectable with an input select signal.

16. The method of interfacing a lower voltage portion of an integrated circuit with a higher voltage portion of said integrated circuit according to claim 14, wherein:
said predetermined percentage is approximately 0%.

17. The method of interfacing a lower voltage portion of an integrated circuit with a higher voltage portion of said integrated circuit according to claim 14, wherein:
said predetermined percentage is approximately 10%.

18. The method of interfacing a lower voltage portion of an integrated circuit with a higher voltage portion of said integrated circuit according to claim 14, wherein:
said predetermined percentage is approximately 20%.

19. Apparatus for interfacing a lower voltage portion of an integrated circuit with a higher voltage portion of said integrated circuit, comprising:
means for allowing a lower voltage signal from said lower voltage portion of said integrated circuit to pass through a translator-up circuit before driving an output driver in said higher voltage portion; and
means for allowing said lower voltage signal to bypass said translator-up circuit when a voltage level of a power rail of said lower voltage portion is within a predetermined percentage of a voltage level of a power rail of said higher voltage portion.

20. The apparatus for interfacing a lower voltage portion of an integrated circuit with a higher voltage portion of said integrated circuit according to claim 19, further comprising:
means for selectably controlling said bypass with an input select signal.

21. The apparatus for interfacing a lower voltage portion of an integrated circuit with a higher voltage portion of said integrated circuit according to claim 19, wherein:
said predetermined percentage is approximately 0%.

22. The apparatus for interfacing a lower voltage portion of an integrated circuit with a higher voltage portion of said integrated circuit according to claim 19, wherein:
said predetermined percentage is approximately 10%.
